(19) United States
(12) Patent Application Publication
(10) Pub. No.: US 2005/0126623 A1
(43) Pub. Date: Jun. 16, 2005

(54) Thin layer energy system

(76) Inventors: Wolfgang Rogler, Mohrendorf (DE); Christoph Brabec, Erlangen (DE)

Correspondence Address: YOUNG & THOMPSON, 745 SOUTH 23RD STREET, 2ND FLOOR, ARLINGTON, VA, 22202, US

(21) Appl. No.: 10/498,484

(22) PCT Filed: Dec. 12, 2002
(86) PCT No.: PCT/DE02/04563

(30) Foreign Application Priority Data
Dec. 13, 2001 (DE) 101 61 303.2

(51) Int. Cl. H01L 31/00

(52) U.S. Cl. 136/253; 136/252

(57) ABSTRACT

The combination of at least one thin layer energy storage system with at least one thin layer energy converter is disclosed. Solar cells are preferably applied as energy converters and particularly preferred are those having at least one organic functional polymer and/or are flexible. The energy converter should meet the mechanical requirements of a mobile thin layer energy system and at the same time be incorporated in the production chain with as few problems as possible.

The invention relates to a thin-film energy system.

There are known thin-film energy systems such as batteries for mobile phones, handheld computers or similar portable electronic components.

A thin-film energy system includes at least one energy store, such as an accumulator and/or a battery and/or a capacitor constructed in thin-film form, that is to say built up on a thin substrate with an overall installation height for the complete energy store in the millimeter range. In some cases, the associated energy stores, that is the accumulators and/or batteries and/or capacitors, must have a high level of mechanical flexibility, so that they can be used in functional smart cards such as banking machine cards or telephone cards with supplementary functions. An example of such a thin-film energy store is a lithium/polymer electrolyte battery with an installation height of approximately 1 μm to 10 mm. It is preferable if thin-film energy systems are flexible.

A disadvantage of the known systems is that they have a short service life by comparison with the devices which they drive and, on the one hand, they are practically unrechargeable, because the electrical devices for recharging them are bulky, demanding and expensive and, on the other hand, the systems are not suitable for direct replacement because it is difficult to replace these smallest of components.

There is therefore a need to produce rechargeable portable thin-film energy systems which, in spite of having a long service life, have an installation height in the same range as the thin-film energy systems.

The object of the present invention is therefore to make available rechargeable portable thin-film energy systems.

The subject of the invention is a thin-film energy system with at least one rechargeable thin-film energy store and at least one thin-film energy converter, where the energy converter has an electrically conducting link to the rechargeable energy store.

In accordance with one form of embodiment, the energy converter incorporates at least one photo-voltaic cell.

In accordance with one form of embodiment, the photo-voltaic cell incorporates at least one organic functional polymer. Particularly preferred is a flexible photo-voltaic cell.

The term “organic functional polymer” means any film in a semi-conductor component which is not made of the material of conventional semiconductor technology based on silicon. No restriction is made in terms of molecular size, such as might be assumed from the expression “. . . polymer”, but instead even so-called “small molecules” could be included under this term. The components with organic functional polymers are preferably attached to flexible substrates.

The term “thin-film energy system” would, for example, be applied to a flexible energy system with an installation height in the range between 1 μm and 10 mm, preferably between 10 μm and 1000 μm.

Preferably, the energy converter will be an organic photo-voltaic cell which can be manufactured by thin-film methods and has an installation height between 1 μm and 8 μm.

For the energy store, use can be made of any accumulators/batteries/capacitors for which the installation height does not significantly exceed the dimension cited.

In accordance with one form of embodiment, the photo-voltaic cell is directly integrated into the energy store so that, for example, one electrode is a common electrode, and is used by both the photo-voltaic cell and the energy store.

In accordance with another form of embodiment, the photo-voltaic cell is not directly integrated into the energy store, but merely combined in a shared package (joint packaging).

The thin-film energy system is preferably portable, that is it can be operated independently of any mains power supply connection.

The invention is explained in more detail below by reference to two figures, which show forms of embodiment of the invention:

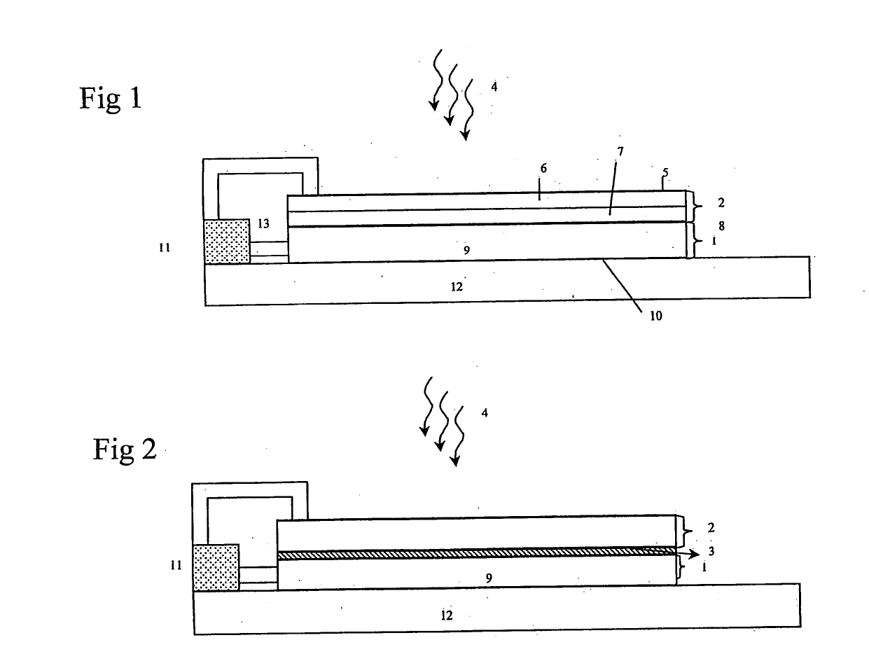

FIG. 1 shows an example in which the energy converter, e.g. the photo-voltaic cell, is placed on one of the store's electrodes.

FIG. 2 shows an example in which the energy converter, e.g. the photo-voltaic cell, is joined to the store by a joining and/or protective layer.

FIG. 1 shows a combination of a thin-film energy store 1 with a thin-film solar cell 2. When this is illuminated the light, symbolized by the arrows 4, falls on the transparent top electrode 5 (anode or cathode) of the photo-voltaic cell 2. The light penetrates as far as the photo-voltaically active area 6 of the photo-voltaic cell 2 which may be connected to the other electrode 8 (anode or cathode) by a conductive polymer film 7. The electrode 8 is a common electrode of the solar cell 2 and the energy store 1. Accordingly, it is bounded by the energy storage medium 9 which is based, for example, on an electrolyte. Connected to the energy storage medium 9 is the opposite electrode of the energy store 10 (anode or cathode) which, for its part, is connected to the electrode current collector 13, which is connected to charging electronics 11. The entire system is attached to a substrate 12.

The form of embodiment shown in FIG. 1 exhibits a combination of an energy store 1, i.e. battery/accumulator/capacitor system with a thin-film solar cell 2, in which the solar cell 2 is placed on the storage electrodes 8. The solar cell 2 and the energy store 1 can be jointly protected and packaged by a semi-transparent seal. Here, the solar cell 2 can cover either the entire area of the store 1, or only part of it. Equally, the store 1 can cover the entire area of the solar cell 2, or only part of it. It is also possible to use a conductive polymer film 7 with electrode characteristics. Examples of this are PEDOT, PANI, polypyrrol, etc.).

The arrangement of the electrodes of the store 1 and the solar cell 2 is chosen such that by using suitable charging electronics 11 the solar cell 2 charges up the store 1, but otherwise does not affect the withdrawal of energy from the store 1.

FIG. 2 shows the combination of a thin-film energy store 1, e.g. an accumulator/capacitor and/or battery system with a thin-film solar cell 2, in which the solar cell 2 is connected to the energy store 1 by a suitable joining film 3. The solar cell 2 can be manufactured on this film 3, or a finished solar cell 2 can be placed onto this film. The common film 3 can fulfill other functions, e.g. as a sealing and/or protective film for one of the two components 1 or 2, or for both components. It is also possible to connect together electrically the two components, 1 and 2, that is the energy store 1 and the solar cell 2, within or on the joining film 3. Depending on the arrangement of the solar cell 2, it may be better for the joining film 3 to be a semi-transparent sealing film/protective film/electrically conductive or insulating film. According to one form of embodiment, the solar cell 2 is so arranged that the substrate 12 of the solar cell 2 (e.g. polyester/ITO for organic-based solar cells) is used as a terminating film for the surface towards the outside environment.

The arrangement of the electrodes (anode/cathode) of the energy storage system and of the solar cell is chosen such that, by using suitable charging electronics 11, the solar cell 2 charges up the energy storage system 1, but otherwise does not affect the withdrawal of energy from the store 1.

The invention proposes the combination of at least one thin-film energy storage system with at least one thin-film energy converter. Preferably, solar cells will be used as the energy converters, and particular preference is given to those which include at least one organic functional polymer and/or are flexible. The energy converter should meet the mechanical demands on a portable thin-film energy system and at the same time should be capable of being incorporated into the production chain with as few problems as possible.

1. A thin-film energy system comprising:
at least one rechargeable thin-film energy store; and
at least one thin-film energy converter,
wherein the energy converter has an electrically conducting link to the rechargeable thin-film energy store, and the thin-film energy system has an installation height in the range of 1 μm to 10 mm.

2. The thin-film energy system in accordance with claim 1, wherein the thin-film energy converter incorporates at least one photo-voltaic cell.

3. The thin-film energy system in accordance with claim 2, wherein the photo-voltaic cell incorporates at least one functional organic polymer.

4. (canceled)

5. The thin-film energy system in accordance with claim 1, which is flexible.

6. The thin-film energy system in accordance with claim 1, wherein the thin-film energy converter is directly integrated into the thin-film energy store.

7. The thin-film energy system in accordance with claim 1, wherein the thin-film energy converter is integrated with the thin-film energy store via a shared electrode.

8. The thin-film energy system in accordance with claim 1, wherein the thin-film energy converter is integrated with the thin-film energy store via a joining film.

9. The thin-film energy system in accordance with claim 1, which is portable.

10. The thin-film energy system in accordance with claim 5, wherein the thin-film energy converter is directly integrated into the thin-film energy store.

11. The thin-film energy system in accordance with claim 5, wherein the thin-film energy converter is integrated with the thin-film energy store via a shared electrode.

12. The thin-film energy system in accordance with claim 5, wherein the thin-film energy converter is integrated with the thin-film energy store via a joining film.

13. The thin-film energy system in accordance with claim 3, wherein the thin-film energy converter is directly integrated into the thin-film energy store.

14. The thin-film energy system in accordance with claim 3, wherein the thin-film energy converter is integrated with the thin-film energy store via a shared electrode.

15. The thin-film energy system in accordance with claim 3, wherein the thin-film energy converter is integrated with the thin-film energy store via a joining film.

16. The thin-film energy system in accordance with claim 2, wherein the thin-film energy converter is directly integrated into the thin-film energy store.

17. The thin-film energy system in accordance with claim 2, wherein the thin-film energy converter is integrated with the thin-film energy store via a shared electrode.

18. The thin-film energy system in accordance with claim 2, wherein the thin-film energy converter is integrated with the thin-film energy store via a joining film.

19. A thin-film energy system, comprising:
at least one rechargeable thin-film energy store; and
at least one thin-film energy converter that integrated with the thin-film energy store via a shared electrode.

20. The thin-film energy system of claim 19, wherein the thin-film energy converter incorporates at least one photo-voltaic cell.

21. The thin-film energy system of claim 20, wherein the photo-voltaic cell comprises at least one functional organic polymer.
